(19) United States
(12) Patent Application Publication
(10) Pub. No.: US 2010/0092876 A1
(43) Pub. Date: Apr. 15, 2010

(54) METHOD FOR REPAIRING PHOTO MASK, SYSTEM FOR REPAIRING PHOTO MASK AND PROGRAM FOR REPAIRING PHOTO MASK

(76) Inventor: Shingo KANAMITSU, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/569,727

(22) Filed: Sep. 29, 2009

(30) Foreign Application Priority Data
Sep. 30, 2008 (JP) 2008-255639

(51) Int. Cl. G03F 1/00; G06K 9/00

(52) U.S. Cl. 430/5; 382/144

(57) ABSTRACT

There is provided a method for repairing a photo mask in this invention, including, obtaining a first image being a photo mask image including a defect area of the photo mask by a repair apparatus, obtaining a second image being a wafer printing image of the photo mask including the defect area by an inspection apparatus, superimposing the first image and the second image to identify a position of the defect area in the first image, and repairing the defect area by the repair apparatus.

### CROSS REFERENCE TO RELATED APPLICATION

This application is based upon and claims the benefit of priority from the prior Japanese Patent Application No. JP2008-255639, filed Sep. 30, 2008; the entire contents of which are incorporated herein by reference.

### FIELD OF THE INVENTION

The present invention relates to a method for repairing a defect in a photo mask, a system for repairing the defect in the photo mask and a program for repairing the defect in the photo mask.

### DESCRIPTION OF THE BACKGROUND

In a fabrication process of a photo mask used in a fabrication of an integrated semiconductor circuit, a mask pattern formed on a photo mask substrate is necessary. Checking the photo mask determines that the mask pattern is good or not, in other word, criteria for acceptance are satisfied or not. As the checking method for the photo mask, observing by using an inspection apparatus having the same optical system as an aligner used for a wafer printing is an ideal approach.

In general, the inspection apparatus having the same wavelength and an optical system with the aligner has been used as disclosed in Japanese Patent Publication (Kokai) No. 2003-140321. Actually, a pattern image is obtained by setting an illuminating condition which is the same condition with an exposure condition of an aligner used in fabricating a semiconductor device when a mask pattern is printed on a wafer. The photo mask is inspected by evaluating the pattern image.

When a defect to be repaired are detected in the inspection process by the inspection apparatus, the defect is subsequently repaired in a repair apparatus. A defect coordinate information are output from the inspection apparatus to the repair apparatus to move into a defect coordinate in the repair apparatus in the processing steps mentioned above.

However, the image obtained by the repair apparatus is relatively lower resolution. Therefore, in a case that a micro defect is detected by the inspection apparatus, a position of the micro defect cannot be clearly specified so as to generate a difficult problem.

### SUMMARY OF THE INVENTION

According to an aspect of the invention, there is provided a method for repairing a photo mask, including, obtaining a first image being a photo mask image including a defect area of the photo mask by a repair apparatus, obtaining a second image being a wafer printing image of the photo mask including the defect area by an inspection apparatus, superimposing the first image and the second image to identify a position of the defect area in the first image, and repairing the defect area by the repair apparatus.

Further, another aspect of the invention, there is provided a system for repairing a photo mask including, a repair apparatus portion obtaining a first image being a photo mask image including a defect area, an inspection apparatus portion obtaining a second image being a wafer printing image of the photo mask including the defect area, a feed portion feeding the photo mask between the inspection apparatus portion and the repair apparatus portion, an information memory portion storing the first image and the second image, a calculating portion superimposing the first image and the second image to identify a position of the defect area in the first image, and a control portion controlling operations of the repair apparatus portion, the inspection apparatus portion, the feed portion, the information memory portion and the calculating portion.

Further, another aspect of the invention, there is provided, a program a photo mask executing a computer including, a step for obtaining a first image being a photo mask image including a defect area by a repair apparatus, a step for obtaining a second the image being a wafer printing image including the defect area by a inspection apparatus, a step for superimposing the first image and the second image to identify a position of the defect area in the first image, and a step for repairing the defect area by the repair apparatus.

### BRIEF DESCRIPTION OF THE DRAWINGS

FIG. 1 is a plain view showing a method for repairing a defect in a photo mask according to a first embodiment of the present invention;

FIG. 2 is a cross-sectional view showing the method for repairing the defect in the photo mask according to the first embodiment of the present invention;

FIG. 3 is a plain view showing the method for repairing the defect in the photo mask according to the first embodiment of the present invention;

FIG. 4 is a plain view showing the method for repairing the defect in the photo mask according to the first embodiment of the present invention;

FIG. 5 is a cross-sectional view showing the method for repairing the defect in the photo mask according to the first embodiment of the present invention;

FIG. 6 is a cross-sectional view showing the method for repairing the defect in the photo mask according to the first embodiment of the present invention;

FIG. 7 is a plain view showing a method for repairing a defect in a photo mask according to a second embodiment of the present invention;

FIG. 8 is a block diagram showing a system for repairing a defect in a photo mask according to a third embodiment of the present invention;

FIG. 9 is a flow chart showing an executing process of a program for repairing a defect in a photo mask according to a fourth embodiment of the present invention.

### DETAILED DESCRIPTION OF THE INVENTION

Embodiments of the present invention will be described below in detail with reference to the attached drawings. It should be noted that the present invention is not restricted to the embodiments but covers their equivalents. Throughout the attached drawings, similar or same reference numerals show similar, equivalent or same components.

### First Embodiment

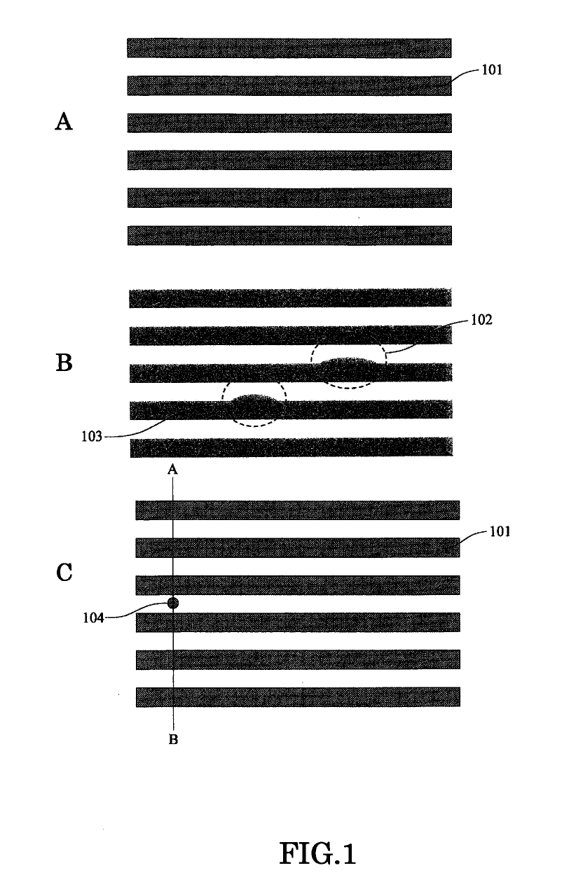

First, a method for repairing a defect in a photo mask according to a first embodiment of the present invention will be described below in detail with reference to FIGS. 1-6.

FIG. 1A represents an image of a mask pattern 101 with a plurality of lines and spaces formed on a photo mask substrate by scanning electron microscopy. fabrication process of a photo mask, it is necessary to evaluate that the photo mask fabricated by a fabrication process is good or not, namely, criteria for acceptance are satisfied or not. Ideally, the mask pattern is practically printed on a wafer by using the photo mask which is repaired and subsequently the mask pattern formed on the wafer is evaluated.

For satisfying the demand, in general, an inspection apparatus having the same wavelength and an optical system with an aligner is used. The aligner is used in printing a pattern. A pattern image is obtained by setting an illuminating condition which is the same condition with an exposure condition of the aligner used in fabricating a semiconductor device when the mask pattern is printed on a wafer. The photo mask is inspected by evaluating the pattern image.

FIG. 1B shows an image of the photo mask as shown in FIG. 1A which is observed by the inspection apparatus. An abnormal printing areas 102 and 103 or the like can be observed by using the inspection apparatus. The abnormal printing areas 102 and 103 are constituted with micro defects or the like which are not normally printed as defect patterns by the repair apparatus because of being difficult in detecting an image. After positions, sizes or the like of the abnormal printing areas 102 and 103 are evaluated, the photo mask is judged as normal when prescribed criteria for evaluation are satisfied.

On the other hand, the photo mask is judged to be necessary for repairing by the repair apparatus when the criteria for evaluation are not satisfied. Consequently, the photo mask is fed to the repair apparatus. In the repair apparatus, identification on a defect position to be repaired is carried out according to a defect coordinate information output from the inspection apparatus. Therefore, the photo mask which is held in a stage of the repair apparatus is moved to an assigned coordinate on the basis of the defect coordinate information.

When the moving process is carried out, a feeding error is conventionally in a range of one micrometer to a couple of micrometers. On basis of the defect coordinate information output from the inspection apparatus, the photo mask is moved to a defect coordinate. However, it is difficult to identify the position of the defect to be repaired in the repair apparatus. The defect may be set in a visual field; however, the position information cannot be detected below 0.1 μm as degree of accuracy, after moving to the defect coordinate and obtaining the image as the repair apparatus.

The defect size in this embodiment is mainly below 0.1 μm. Furthermore, the defect size in a CD error system also includes in the vicinity of 0.01 μm. software other than viewing by eyes is necessary to identify the position of the defect to be repaired after obtaining the image by the repair apparatus.

When a resolution of the image by the repair apparatus is sufficiently high, a problem is not occurred. However, the repair apparatus having sufficiently high resolution to the defect size mentioned above is not existed in the present status. Accordingly, it is difficult to detect the defect in a case without a characteristic pattern as a mark, for example, the pattern with lines and spaces.

An EB repair apparatus has so high image resolution that has capability of identifying the position of the defect to be repaired as compared to other repair apparatus. However, the capability is not sufficient. Furthermore, the EB repair apparatus may not detect some kinds of detect defects. For example, a CD error defect which is a line being widen in nanometer order along the line over micrometers. In the case, a line portion in the visual field is divided into a prescribed interval. Inspecting the overall portion may introduce to detect the defects. However, identifying the position may be difficult in combining with vibration component being interposed on the image and pattern roughness.

As shown in FIG. 1C, this embodiment has a technical feature mentioned below as a solution of the problem mentioned above. when the defect to be repaired is detected in the inspection process by the inspection apparatus, an alignment mark 104 is formed on a space without the mask pattern 101 in the repair apparatus. The alignment mark 104 may be a size which is detectable in an image obtained in the inspection apparatus. For example, a dot pattern having 150 nm diameter is formed in a case of a space size being 260 nm.

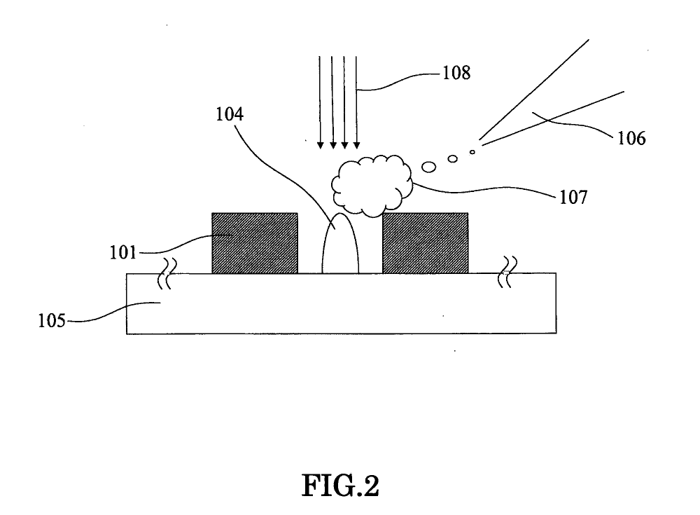

FIG. 2 is a cross-sectional view cut along A-B line in FIG. 1C. As shown in FIG. 2, it is desirable that the alignment mark 104 is formed by a deposition method which induces less damage to a photo mask substrate 105. Especially, the EB repair apparatus is desirable for performing the deposition by using an electron beam or an ion beam 108 to be able to suppress the damage to the photo mask substrate 105 at minimum. Actually, the alignment mark 104 may be formed by chemical vapor deposition (CVD) using a deposition gas 107 being inlet from a gas nozzle 106 and the electron beam or the ion beam 108. When SiO₂ is formed as the alignment mark 104, Tetra Ethyl Ortho Silicate (TEOS) or the like can be used as the deposition gas 108.

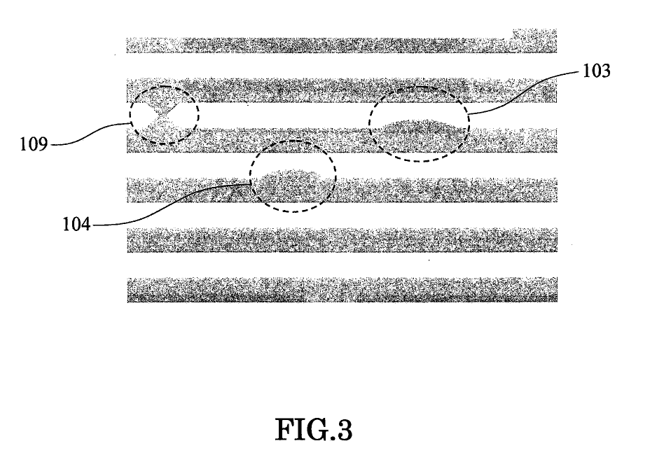

After finishing the processing steps mentioned above, the alignment mark 104 can be detected as a area with changing photo strength profile 109, the image is again obtained by the inspection apparatus as shown in FIG. 3. In spite of a case that the image obtained by the inspection apparatus is different from the image obtained by the repair apparatus in a scale, an interval between the alignment mark 104 and a position to be repaired in the image obtained by the inspection apparatus can be clear. Accordingly, processing the repair position can be carried out on the basis of the information on the position relation in the repair apparatus.

As a method for simply and precisely performing this work, for example, using an image matching is proposed. First, a first image including the alignment mark 104 and a portion to be repaired is clipped on the image obtained by the inspection apparatus. On the other hand, a second image corresponding to the first image is also clipped on the image obtained by the repair apparatus. Subsequently, the first image and the second image are superimposed. In these processing steps, corrections of the first image and the second image are preliminary necessary to coincide with magnification or corresponding relations of rotation and mirror between the two images. Furthermore, an image processing to convert an upper image as transparent is also necessary so as to be able to view an under image when the two image, first image and the second image, are superimposed.

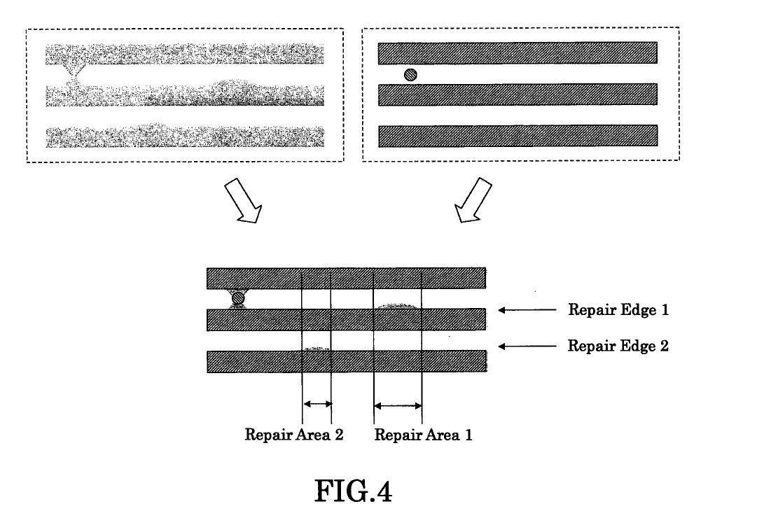

FIG. 4 is a superposition image obtained by the approach mentioned above. As shown in FIG. 4, a pattern edge to be repaired and an interval between the pattern edges can easily obtain as reference to the superposition image. The information being fed back from the first image obtained by the inspection apparatus determines on a repair degree of the second image obtained by the repair apparatus. Consequently, the repair processing steps are carried out as mentioned below when a plurality of areas are repaired and each area has different repair conditions each other as shown in FIG. 4. The repair conditions can be determined by preliminary obtaining data of the mask pattern on transparent ratio, size variation or the like in each area.

As determining the repair conditions, for example, an unnecessary printing area in a repair area 1 is larger than that in a repair area 2. Therefore, when repairing the repair area 1, a removing parameter of the repair area 1 is set as larger than that of the removing parameter of the repair area 2. The removing parameter is adjusted by variation of a dose amount in the repair apparatus with a beam system, for example, the EB repair apparatus or the FIB repair apparatus, and by variation of an edge bias or a probe pressure parameter, for example, in the AFM repair apparatus.

After the repair process by the repair apparatus mentioned above is over, the repaired area is again evaluated by the inspection apparatus to judge for satisfying evaluation criteria. When the evaluation criteria are not satisfied, the repair process is again performed. The repair process and the evaluation process are repeated to satisfy the criteria for evaluation. When the repair process is again performed, an area or a repair amount to be repaired may be changed by the previously repaired process. Therefore, it is desirable that the two images, the first image and the second image, are again superimposed to reset the repair condition.

On the other hand, when the evaluation criteria are satisfied, the processing steps move to remove the alignment mark 104. As removing the alignment mark 104, for example, etching by beam irradiation in the repair apparatus, for example, the EB repair apparatus, the FIB repair apparatus or the like is used, or removing by using a probe, for example, in the AFM repair apparatus, is used.

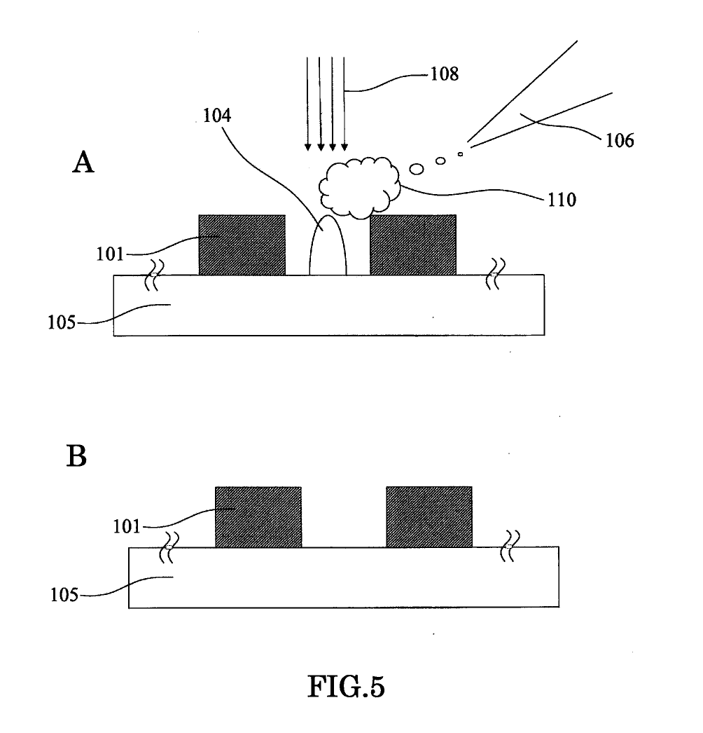

FIG. 5 is the method for removing the unnecessary printing area removed by beam irradiation in the repair apparatus, for example, the EB repair apparatus, the FIB repair apparatus or the like. As shown in FIG. 5A, a etching gas 111 being inlet from a gas nozzle 110 and irradiating an ion beam or an electron beam 112 to the alignment mark 104 so as to react between the etching gas 111 and the alignment mark 104. As a result, the alignment mark 104 is removed as shown in FIG. 5B. A thickness of the alignment mark 104 is preliminary measured and the alignment mark 104 is constantly formed as the same thickness. In this case, a condition of the removing is also determined as a constant condition. Therefore, the alignment mark 104 can be simply removed by the processing steps mentioned above. When SiO₂ is used as the alignment mark 104, XeF₂ or the like is used as the etching gas 111.

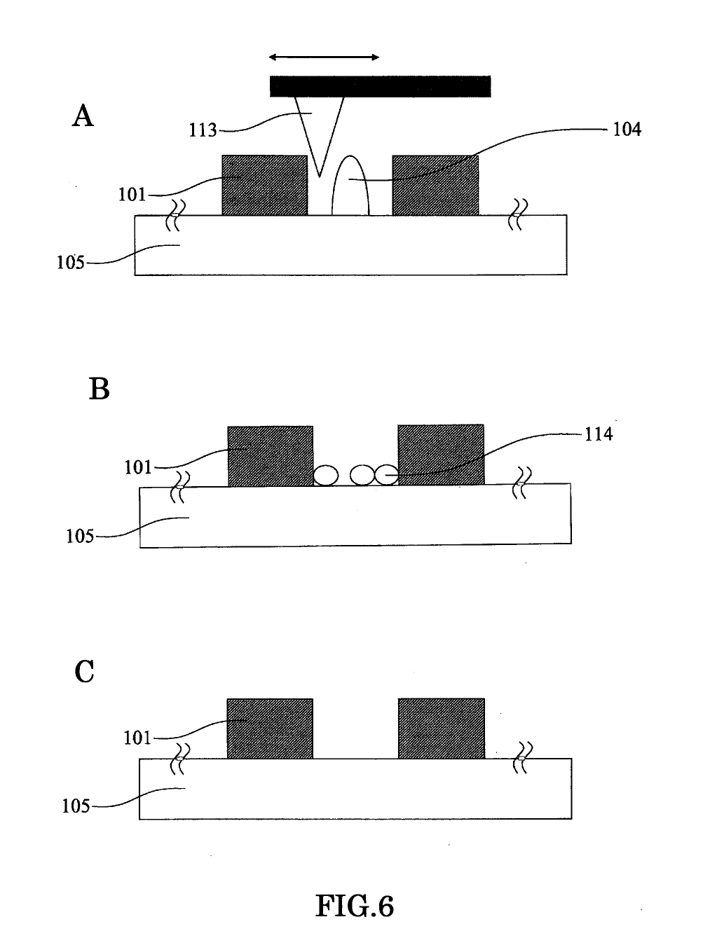

Further, FIG. 6 is the method for removing the unnecessary printing area by using the AFM repair apparatus. As shown in FIG. 6(a), the alignment mark 104 is removed by contacting a probe 113 with the alignment mark 104. As shown in FIG. 6(b), a fragment 114 of the alignment mark 104 may be leaved on the photo mask substrate 105, it is necessary to remove the fragment 114 by cleaning. As a method for removing the fragment 114, dry cleaning by using dry ice powder spray generally used can be applied or wet cleaning by using sulfuric acid, hydrogen peroxide solution or the like conventionally used in a fabrication process of a mask can be applied as shown in FIG. 6(c).

After the alignment mark 104 is removed, the alignment mark 104 being normally removed is confirmed by the inspection apparatus to complete processing steps for repairing the defects in the mask.

As mentioned above, the inspection is carried out by the inspection apparatus to detect the defect to be repaired in the first embodiment. In the case, the alignment mark 104 is formed in the repair apparatus. The image information obtained in the inspection apparatus precisely teach the position information of the defect to be repaired in the repair apparatus.

As a result, a situation on the defect which may be repaired in the repair apparatus but cannot be repaired for difficulty of detecting the position can be avoided. Further, precisely aligning on the defect can be performed when the pattern usable for aligning is not in the image surrounding the area to be repaired. Further, a miss-removing in the removing process can be suppressed in the repair process. Namely, a yield of the photo mask can be improved by using the defect repair method of the photo mask according to the first embodiment of the present invention. Accordingly, a fabrication cost of the photo mask or turn around time of the fabrication process can be suppressed to be low.

### Second Embodiment

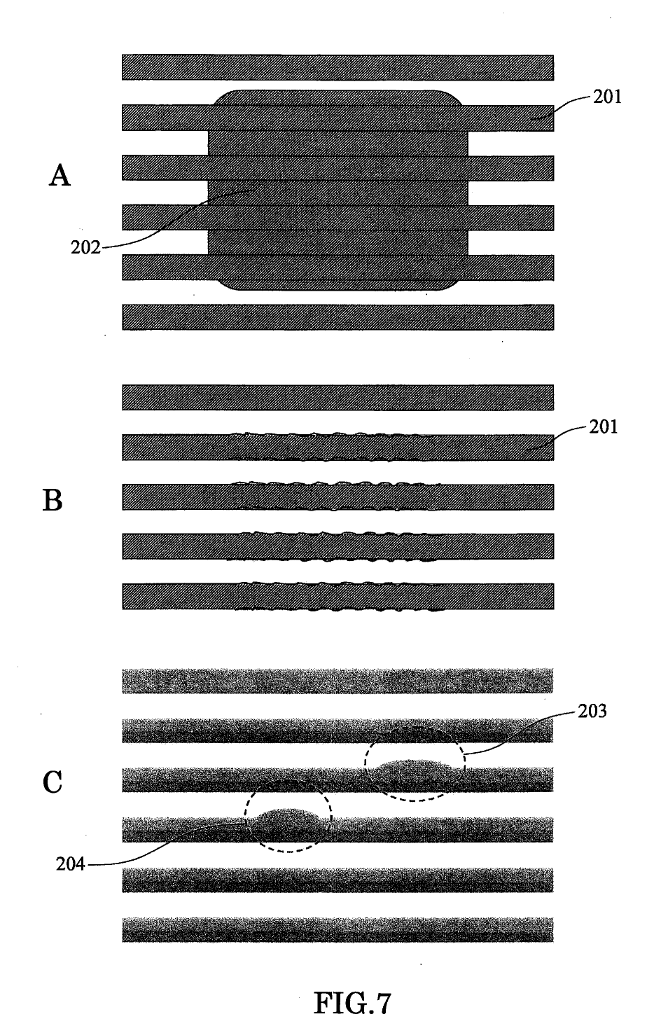

Next, a method for repairing a defect in a photo mask according to a second embodiment of the present invention will be described below in detail with reference to FIG. 7.

FIG. 7A shows an image of a mask pattern 201 with a plurality of lines and spaces formed on a photo mask substrate by scanning electron microscopy when a black defect 202 is formed over the plurality of lines and spaces. The second embodiment has a difference with the first embodiment where not only micro defects detected by an inspection apparatus but also damage defects generated on the repaired area at the previous repair process can be applied to a repairing process.

As shown in FIG. 7A, when the black defect 202 is formed over the mask pattern 201 with plurality of the lines and spaces, a portion of the black defect 202 formed on the spaces between the lines is repaired by the repair apparatus. Practically, FIB, laser, AFM, EB or the like is applied to the repairing process to remove the portion of the black defect 202 formed on the spaces between the lines in the mask pattern. FIG. 7B shows an image of the photo mask removed the portion of the black defect 102 to be repaired by the repair apparatus. The portion of the black defect 202 which is formed on an unnecessary area is removed. Judge on the image obtained by the repair apparatus introduces to assume that the area is fully repaired.

It is necessary to evaluate for the photo mask repaired by the repair apparatus that the photo mask fabricated by a fabrication process is good or not, namely, criteria for acceptance are satisfied or not. The inspection apparatus is applied to an evaluation method as the same as the first embodiment.

FIG. 7C shows an image of the photo mask as shown in FIG. 7B which is observed by the inspection apparatus. Abnormal printing areas 203 and 204 or the like can be observed by using the inspection apparatus. On the other hand, the abnormal printing areas 203 and 204 are constituted with micro defects or the like which are not normally printed as defect patterns by the repair apparatus because of being difficult in detecting images of the micro defects or the like. After positions, sizes or the like of the abnormal printing areas 203 and 204 are evaluated, the photo mask is judged as normal when prescribed criteria for evaluation are satisfied.

On the other hand, the photo mask is judged to be necessary for repairing by the repair apparatus when the evaluation criteria are not satisfied. Consequently, the photo mask is fed to the repair apparatus. A method for repairing the defect in the repair apparatus is the same as that in the first embodiment, therefore, an explanation is omitted. The repair process is again necessary when the previous repair process is not completed. In this case, a repairing process of the repaired mask pattern has difficulty for repairing again on the same area. As a taper shape of the pattern edge is different from an original taper shape so that judgment of the repair condition is difficult.

Further, it may be that a size measurement value of the image obtained in the repair apparatus is not coincide with that in the inspection apparatus. Damages can be induced at a removing process where the defects formed on a substrate or the pattern is removed. The induced damages cannot be observed in the repair apparatus. Over-etching, under-etching, Ga stain, river-head, or the like may be generated as the induced damages in the repair apparatus. When a groove as the river-head is formed, the induced damage can be observed by the repair apparatus with high resolution. However, an influence degree of the induced damage to the printing pattern on the wafer cannot be judged in the image obtained by the repair apparatus. Further, estimation by using simulation can be obtained, however, it is a time-absorbing step that the pattern of a three dimension shape is fully installed in a simulator after the repair process.

Furthermore, it is desirable in this embodiment that the alignment mark is formed at the same position as the embedded area with the repaired area when the image is embedded by the repair apparatus.

After the alignment mark 104 is removed, the alignment mark being normally removed is confirmed by the inspection apparatus to complete processing steps for repairing the defect in the mask.

As mentioned above, the inspection is carried out by the inspection apparatus to detect the defect to be repaired in the second embodiment. In the case, the alignment mark is formed in the repair apparatus. The image information obtained in the inspection apparatus precisely teach the position information of the defect to be repaired in the repair apparatus.

Furthermore, the alignment mark is formed on the photo mask in the repair apparatus when a second or later repairing process is performed to the same area as repaired. In this way, the repair error of the photo mask or the induced damage introducing the abnormal printing on the wafer can be precisely repaired by using the method for repairing the photo mask in this embodiment. A repair error cannot be detected by the repair apparatus or cannot be printed a normal pattern on the wafer by the damage in the repairing process.

When performing a plurality of repairs, using the method for repairing the defect in this embodiment may be desired. In this way, a yield of the photo mask can be improved by using the defect repair method of the photo mask according to the second embodiment of the present invention. Accordingly, a fabrication cost of the photo mask or turn around time of the fabrication process can be suppressed to be low.

### Third Embodiment

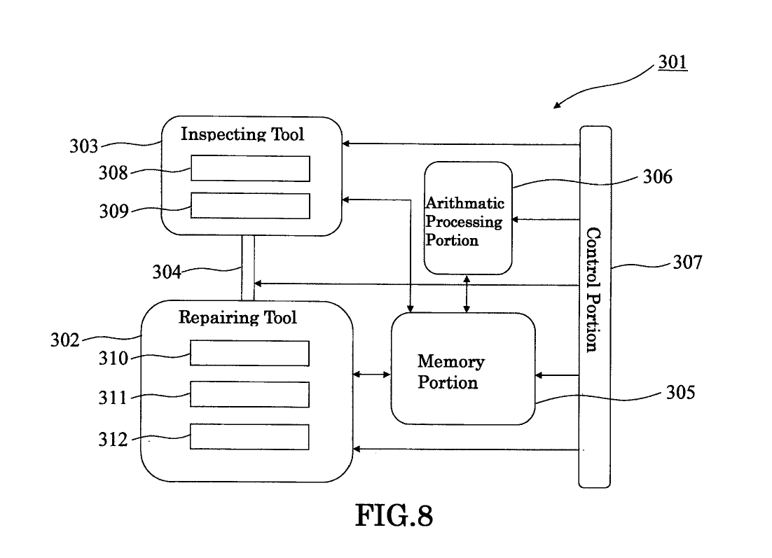

Next, a system for repairing a defect in a photo mask according to a third embodiment of the present invention will be described below in detail with reference to FIG. 8.

FIG. 8 is a block diagram showing a photo mask defect repair system in the third embodiment. A photo mask defect repair system 301 in this embodiment is constituted with an inspection apparatus portion 302, a repair apparatus portion 303, a feed portion 304, a memory portion 305, a calculation portion 306 and control portion 307.

The inspection apparatus portion 302 includes an image extraction portion 308 and a memory portion 309. The image extraction portion 308 extracting entirely same exposure condition when a device is fabricated. Therefore, a pattern image formed on a wafer is obtained when the mask pattern is printed on the wafer and information of the pattern image is stored in a memory portion 309.

The repair apparatus portion 303 is constituted with an image extraction portion 310, a repair portion 311 and a memory portion 312. The image extraction portion 310 obtains the image of the photo mask by scanning electron microscopy or the like. The repair portion 311 repairs the photo mask and removes the alignment mark. The memory portion 312 stores the image obtained in the image extraction portion. Furthermore, the feed portion 304 is configured between the inspection apparatus portion 302 and the repair apparatus portion 303 to feed the photo mask between the inspection apparatus portion 302 and the repair apparatus portion 303.

The memory portion 305 can stores information, programs or the like. The information includes a fabricating method, fabricating conditions or a removing method of the alignment mark, magnification or corresponding relations of rotation and mirror between the two images obtained in the repair apparatus and the inspection apparatus. The programs include executing for the control portion 307. The calculation portion 306 determines superimposing the images obtained in the inspection apparatus portion 302 and the repair apparatus portion 303 and the repair condition on the basis of the interposition. The control portion 307 controls on each portion on the basis of the program stored in the memory portion 305.

As mentioned above, the defect repair method of the photo mask in the first embodiment and the second embodiment can be performed by the defect repair system of the photo mask in this embodiment.

In the word, a yield of the photo mask in this embodiment can be improved by using the defect repair system of the photo mask in this embodiment. Accordingly, a fabrication cost of the photo mask or a turn around time of the fabrication process can be suppressed low.

### Fourth Embodiment

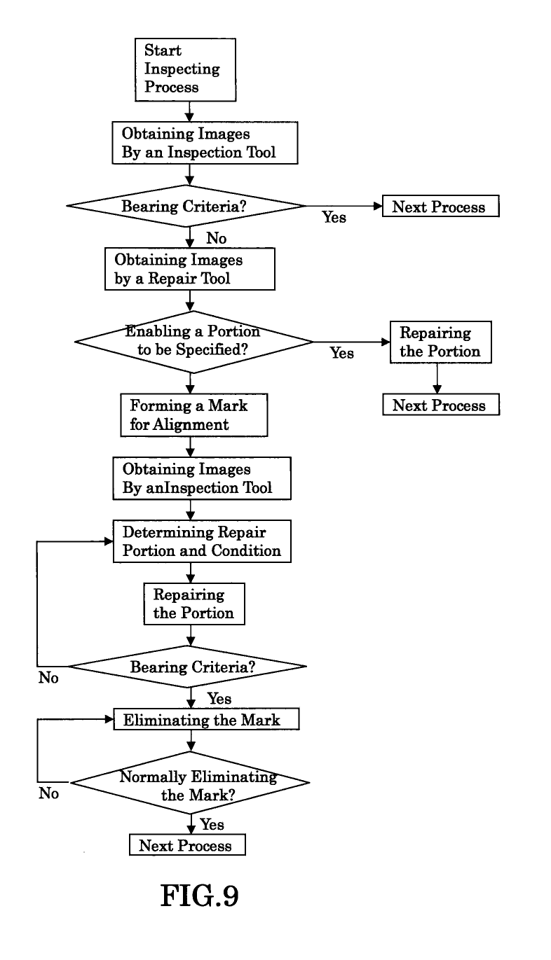

Next, a program for repairing a defect in a photo mask according to a fourth embodiment of the present invention will be described below in detail with reference to FIG. 9. FIG. 9 is a flow chart showing an executing process of a program for repairing a defect in a photo mask according to the fourth embodiment. Furthermore, the method for repairing the defect of the photo mask according to the program in the fourth embodiment is the same as the method for repairing the defect of the photo mask according the first embodiment or the second embodiment. It is to be noted that the same or similar reference numerals are applied to the same or similar parts and elements throughout the drawings, and the description of the same or similar parts and elements will be omitted or simplified.

Before executing the program, information is preliminarily obtained. The information includes a fabricating method, fabricating conditions or a removing method of the alignment mark, a magnification or corresponding relations of rotation and mirror between the two images obtained in the repair apparatus and the inspection apparatus. Furthermore, prescribed evaluation criteria for an image obtain by the inspection apparatus are determined.

First, the photo mask is fed to the inspection apparatus, a judgment which is satisfied the evaluation criteria or not is performed on the image obtained by the inspection apparatus. When the evaluation criteria are satisfied, the photo mask is judged as a good product to be preceded next process. On the other hand, when the evaluation criteria are not satisfied, the photo mask is fed to the repair apparatus. A judgment is performed where the identification of the defect position can be easily detected or not on the repair apparatus (S402). The processing steps may be automatically carried out on the basis of the prescribed evaluation criteria as this embodiment or a viewer may judge the image. When the photo mask is judged as the identification of the defect position which can be easily performed on the repair apparatus, the photo mask is preceded next process through the repair process by the repair apparatus.

On the other hand, when the photo mask which is judges the identification of the defect position cannot as be easily performed on the repair apparatus, the alignment mark is formed on the photo mask by the repair apparatus (S403). After forming the alignment mark, the photo mask is again fed to the inspection apparatus and the image is obtained (S404). Successively, the two images obtained in the inspection apparatus and in the repair apparatus are superimposed to determine the repair area and the repair conditions (S405). Next, the photo mask is fed to the repair apparatus and the photo mask is repaired on the basis of information obtained by the superposition between the two images (S406).

The photo mask is fed to the inspection apparatus and the image is obtained. A judgment is performed where the evaluation criteria are satisfied or not in the mask pattern after the repairing (S407). Subsequently, the photo mask, which is satisfied the evaluation criteria, is fed to the repair apparatus and the alignment mark is removed (S408). The photo mask, which is removed the alignment mark, is fed to the inspection apparatus. The photo mask is judged as the alignment mark is normally removed or not and is preceded next processing steps (S409). When the alignment mark is not normally removed, the photo mask is retuned to the step S408.

When the evaluation criteria are not satisfied in the step S407, the two images obtained in the inspection apparatus and in the repair apparatus are interposed and the repair area and the repair conditions are again determined (S410). Successively, the photo mask is fed to the repair apparatus and the photo mask is repaired on the basis of new conditions determined in the step S410 (S411). Next, the photo mask is fed to the inspection apparatus and the image is obtained. It is judged that the evaluation criteria are satisfied or not in the mask pattern repaired (S412). The steps S410-S412 are repeated till the criteria for evaluation is satisfied.

Further, all the steps S401-S412 in the defect repair program of the photo mask according to this embodiment may not be executed by the computer. For example, the viewer viewing the image may judge that the identification of the defect position can be easily detect in the step S402. Removing the alignment mark and subsequent judging is manually performed to execute the computer. Accordingly, at least the steps S403-S407 may be the program performed by the computer.

As mentioned above, the steps S401-S412 in the defect repair program of the photo mask according to this embodiment can be executed by the computer. Therefore, the information of the defect position to be repaired in the repair apparatus can be precisely detected by the image information obtained in the inspection apparatus. In the word, a yield of the photo mask in this embodiment can be improved by using the defect repair program of the photo mask in this embodiment. Accordingly, a fabrication cost of the photo mask or a turn around time of the fabrication process can be suppressed low.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

What is claimed is:

1. A method for repairing a photo mask, comprising:
obtaining a first image being a photo mask image including a defect area of the photo mask by a repair apparatus;
obtaining a second image being a wafer printing image of the photo mask including the defect area by an inspection apparatus;
superimposing the first image and the second image to identify a position of the defect area in the first image; and
repairing the defect area by the repair apparatus.

2. The method for repairing the photo mask according to claim 1, further comprising:
forming a mark for aligning on the photo mask before the obtaining the first image of the photo mask by the repair apparatus; and
coinciding with the mark in the first image and the mark in the second image in the superimposing the first image and the second image to identify the position of the defect area.

3. The method for repairing the photo mask according to claim 2, wherein
an image matching method is used in the coinciding with the mark in the first image and the mark in the second the image.

4. The method for repairing the photo mask according to claim 3, wherein
a magnification is coincided between the first image and the second image in the image matching method.

5. The method for repairing the photo mask according to claim 3, wherein a corresponding relation between the first image and the second the image is coincided in the image matching method.

6. The method for repairing the photo mask according to claim 3, wherein either the first image or the second image having transparency in the image matching method.

7. The method for repairing the photo mask according to claim 3, wherein a beam deposition technique is used in the forming the mark.

8. The method for repairing the photo mask according to claim 7, wherein the mark is formed by SiO₂.

9. The method for repairing the photo mask according to claim 1, further comprising:
judging for satisfying evaluation criteria or not after the repairing the defect area.

10. The method for repairing the photo mask according to claim 9, further comprising:
identifying the position of the defect area and repairing the defect area by the repair apparatus again when the evaluation criteria for are not satisfied.

11. The method for repairing the photo mask according to claim 9, further comprising:
removing the mark after the judging for satisfying the evaluation criteria on the mark.

12. The method for repairing the photo mask according to claim 11, further comprising:
confirming a removal of the mark after the removing the mark.

13. The method for repairing the photo mask according to claim 11, wherein the beam deposition technique is used in the removing the mark.

14. The method for repairing the photo mask according to claim 11, wherein a method of contacting a probe with the mark is used in the removing the mark.

15. The method for repairing the photo mask according to claim 14, further comprising:
removing a fragment after the removing the mark.

16. The method for repairing the photo mask according to claim 1, further comprising:
preliminarily obtaining a transparent ratio and a size variation value of a prescribed area including the defect area;
determining repairing conditions in the repair apparatus on the basis of the transparent ratio and the size variation value; and
repairing the defect area by using the repairing conditions.

17. The method for repairing the photo mask according to claim 16, wherein a dose amount is used as a parameter of the repairing conditions.

18. The method for repairing the photo mask according to claim 16, wherein an edge bias amount or a probe pressure amount is used as a parameter of the repairing conditions.

19. A system for repairing a photo mask comprising;
a repair apparatus portion obtaining a first image being a photo mask image including a defect area;
an inspection apparatus portion obtaining a second image being a wafer printing image of the photo mask including the defect area;
a feed portion feeding the photo mask between the inspection apparatus portion and the repair apparatus portion;
an information memory portion storing the first image and the second image;
a calculating portion superimposing the first image and the second image to identify a position of the defect area in the first image; and
a control portion controlling operations of the repair apparatus portion, the inspection apparatus portion, the feed portion, the information memory portion and the calculating portion.

20. A program for repairing a photo mask executing a computer comprising;
a step for obtaining a first image being a photo mask image including a defect area by a repair apparatus;
a step for obtaining a second the image being a wafer printing image including the defect area by a inspection apparatus;
a step for superimposing the first image and the second image to identify a position of the defect area in the first image; and
a step for repairing the defect area by the repair apparatus.
